(19) United States
(12) Patent Application Publication
(10) Pub. No.: US 2016/0093377 A1
(43) Pub. Date: Mar. 31, 2016

(54) NONVOLATILE MEMORY MODULE

(71) Applicant: Intel Corporation, Santa Clara, CA (US)

(72) Inventors: Mani Prakash, University Place, WA (US); Edward L. Payton, Olympia, WA (US); John K. Grooms, Webster, MA (US); Dimitrios Ziakas, Hillsboro, OR (US); Mohammed Arafa, Chandler, AZ (US); Raj K. Ramanujan, Federal Way, WA (US); Dong Wang, Shanghai (CN)

(73) Assignee: Intel Corporation, Santa Clara, CA (US)

(21) Appl. No.: 14/498,480

(22) Filed: Sep. 26, 2014

(51) Int. Cl. G11C 14/00; G11C 7/10; G11C 11/406

(52) U.S. Cl. CPC G11C 14/0018; G11C 11/40615; G11C 7/1072

(57) ABSTRACT

Memory modules, controllers, and electronic devices comprising memory modules are described. In one embodiment, a memory module comprises a nonvolatile memory and an interface to a volatile memory bus, at least one input power rail to receive power from a host platform, and a controller comprising logic, at least partially including hardware logic, to convert the power from the input power rail from an input voltage to at least one output voltage, different from the input voltage. Other embodiments are also disclosed and claimed.

### FIELD

The present disclosure generally relates to the field of electronics. More particularly, some embodiments of the invention generally relate to nonvolatile memory modules.

### BACKGROUND

Continuing advances in system architecture, e.g., multi-core processing, and advances in application require corresponding advances in memory systems. Nonvolatile memory systems offer several advantages over volatile memory. However, the ability to adapt existing memory systems (e.g., direct in-line memory modules (DIMMs)) to incorporate nonvolatile memory is limited due to several factors including cost, power management, and thermal management.

Accordingly, techniques to incorporate nonvolatile memory modules into existing memory architectures may find utility.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 is a schematic, block diagram illustration of a system that includes a memory module in accordance with various examples discussed herein.

FIGS. 2A-2B are schematic, block diagrams of an exemplary architecture of a nonvolatile memory module may be implemented in accordance with various embodiments discussed herein.

FIG. 3 is a schematic, block diagram of an electrical architecture of a nonvolatile memory module may be implemented in accordance with various embodiments discussed herein.

FIGS. 4 and 5A-5B are flowcharts illustrating operations in a method to implement a nonvolatile memory module in accordance with various embodiments discussed herein.

FIGS. 6-10 are schematic, block diagram illustrations of electronic devices which may be adapted to implement a nonvolatile memory module in accordance with various embodiments discussed herein.

### DETAILED DESCRIPTION

Described herein are nonvolatile memory modules which are configured to operate in a dual in-line memory module (DIMM) form factor for volatile memory such as Dual Data Rate (DDR) Synchronous Dynamic Random Access Memory (DDS SDRAM). More particularly, described herein are memory modules which incorporate an on-board controller which performs power management functions which enable a memory module compliant with volatile memory, for example, (DDR SDRAM) standards for DIMMs promulgated by the Joint Electronic Device Engineering Council (JEDEC), which is available to the public at the JEDEC website at www.jedec.org under document number JESD79-4, published September, 2012. To accomplish this, a power management controller may be incorporated onto a memory module to convert power from the input power rail from an input voltage to at least one output voltage, different from the input voltage. The power management controller performs additional functions which are described in greater detail below.

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

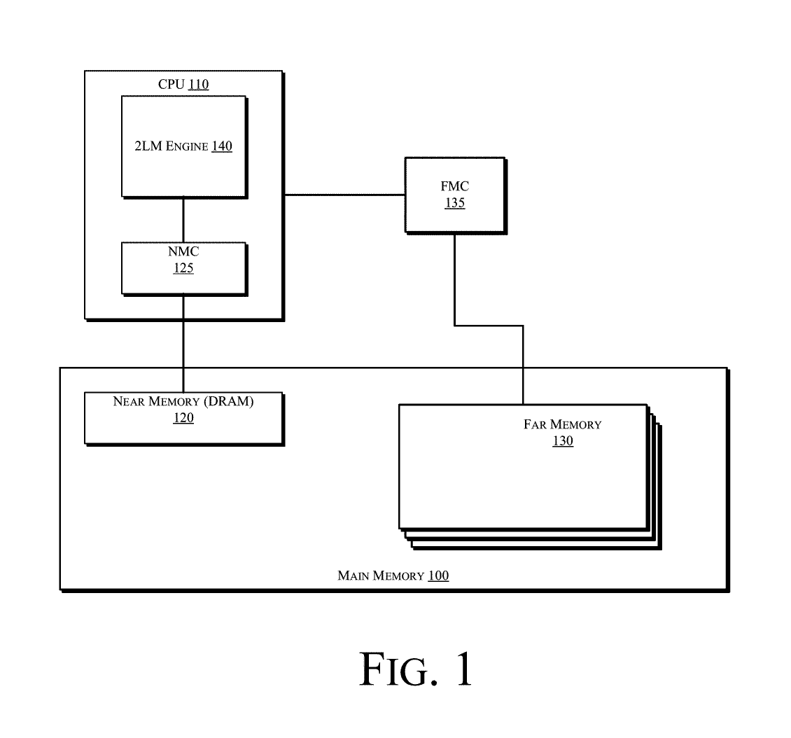

FIG. 1 is a schematic, block diagram illustration of a system that includes a n memory module in accordance with various examples discussed herein. Referring to FIG. 1, system main memory 100 provides run-time data storage and access to the contents of system disk storage memory (not shown) to CPU 110. CPU 110 may include cache memory, which would store a subset of the contents of main memory 100.

In this embodiment there are two levels of memory. Main memory 100 includes a level of volatile memory shown as near memory (DRAM) 120, and a level of memory, shown as far memory 130. Far memory may comprise either volatile memory, e.g., static random access memory (SRAM), a dynamic random access memory (DRAM), nonvolatile memory, or may include nonvolatile memory e.g., phase change memory, NAND (flash) memory, ferroelectric random-access memory (FeRAM), nanowire-based non-volatile memory, memory that incorporates memristor technology, three dimensional (3D) cross point memory such as phase change memory (PCM), magnetoresistive random access memory (MRAM), spin-transfer torque memory (STT-RAM) or NAND flash memory. In this embodiment, near memory 120 serves a low-latency and high-bandwidth (i.e., for CPU 110 access) cache of far memory 130, which may have considerably lower bandwidth and higher latency (i.e., for CPU 110 access).

In this embodiment, near memory 120 is managed by near memory controller (NMC) 125, while far memory 130 is managed by far memory controller (FMC) 135. FMC 135 reports far memory 130 to the system operating system (OS) as main memory-i.e., the system OS recognizes the size of far memory 130 as the size of system main memory 100. The system OS and system applications are “unaware” of the existence of near memory 120 as it is a “transparent” cache of far memory 130.

CPU 110 further comprises a two-level memory (2LM) engine module/logic 140. The “2LM engine” is a logical construct that may comprise hardware and/or micro-code extensions to support two-level main memory 100. For example, 2LM engine 140 may maintain a full tag table that tracks the status of all architecturally visible elements of far memory 130. For example, when CPU 110 attempts to access a specific data segment in main memory 100, 2LM engine 140 determines whether said data segment is included in near memory 120; if it is not, 2LM engine 140 fetches the data segment in far memory 130 and subsequently writes the data segment to near memory 120 (similar to a cache miss). It is to be understood that, because near memory 120 acts as a “cache” of far memory 130, 2LM engine 140 may further execute data prefetching or similar cache efficiency processes known in the art.

The 2LM engine 140 may manage other aspects of far memory 130. For example, in embodiments where far memory 130 comprises nonvolatile memory, it is understood that nonvolatile memory such as flash is subject to degradation of memory segments due to significant reads/writes. Thus, 2LM engine 140 may execute functions including wear-leveling, bad-block avoidance, and the like in a manner transparent to system software. For example, executing wear-leveling logic may include selecting segments from a free pool of clean unmapped segments in far memory 130 that have a relatively low erase cycle count.

It is to be understood that near memory 120 is smaller in size than far memory 130, although the exact ratio may vary based on, for example, intended system use. In this embodiment, it is to be understood that because far memory 130 comprises denser, cheaper nonvolatile memory, main memory 100 may be increased cheaply and efficiently and independent of the amount of DRAM (i.e., near memory 120) in the system.

In various embodiments, at least some of the memory in memory devices 150 may be configured as DIMM devices and may include non-volatile memory, e.g., phase change memory (PCM), a three dimensional cross point memory, a resistive memory, nanowire memory, ferro-electric transistor random access memory (FeTRAM), flash memory such as NAND or NOR, magnetoresistive random access memory (MRAM) memory that incorporates memristor technology, spin transfer torque (STT)-MRAM.

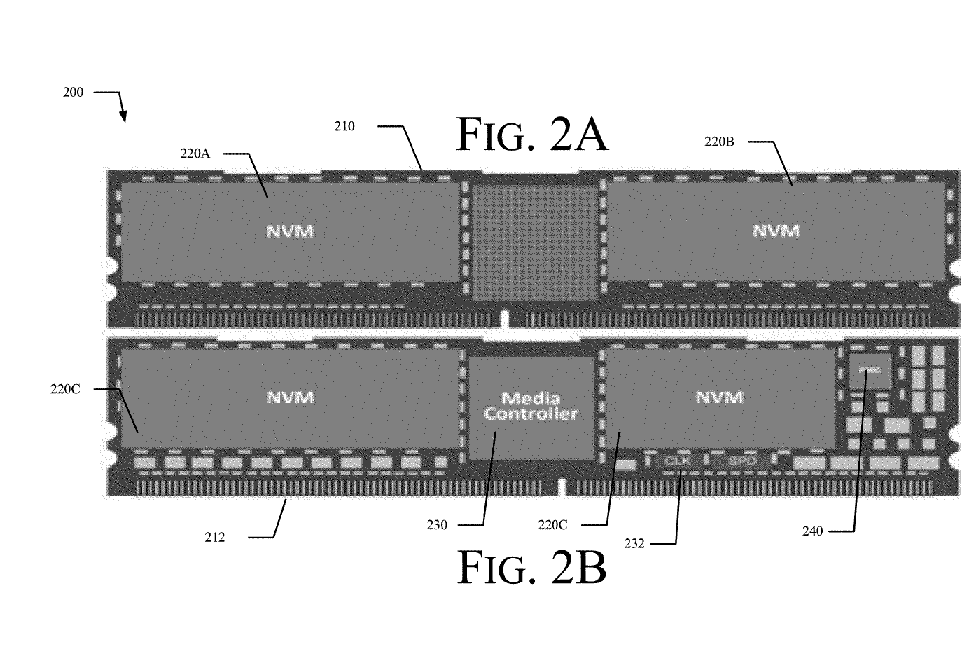

FIGS. 2A-2B are schematic, block diagrams of an exemplary architecture of a nonvolatile memory module may be implemented in accordance with various embodiments discussed herein. More particularly, FIG. 2A depicts a first side and FIG. 2B depicts a second side of a nonvolatile memory module which may be implemented in accordance with various embodiments discussed herein. Referring to FIGS. 2A-2B, in some examples a memory module 200 may comprise a card 210 dimensioned to fit within a DIMM slot and having a plurality of connectors, or pins, 212 positioned to provide electrical contacts with corresponding pins in a DIMM slot on a circuit board of an electronic device.

Memory module 200 may further comprise nonvolatile memory banks 220A, 220B, 220C, 220D, which may be referred to herein collectively by reference numeral 220. As described above, at least some of the memory in memory banks 220 may be configured as DIMM devices and may be implemented non-volatile memory, e.g., NAND (flash) memory, ferroelectric random-access memory (FeRAM), nanowire-based non-volatile memory, memory that incorporates memristor technology, three dimensional (3D) cross point memory such as phase change memory (PCM), spin-transfer torque memory (STT-RAM) or NAND flash memory.

Memory module 200 may further comprise a media controller 230, which may correspond to controller 142 depicted in FIG. 1, a clock 232, and a power management controller 240. In some examples power management controller 240 may be incorporated into an integrated circuit device (e.g., an application specific integrated circuit (ASIC) that is separate from media controller 240. In other examples the power management controller 240 may be integrated into media controller 230.

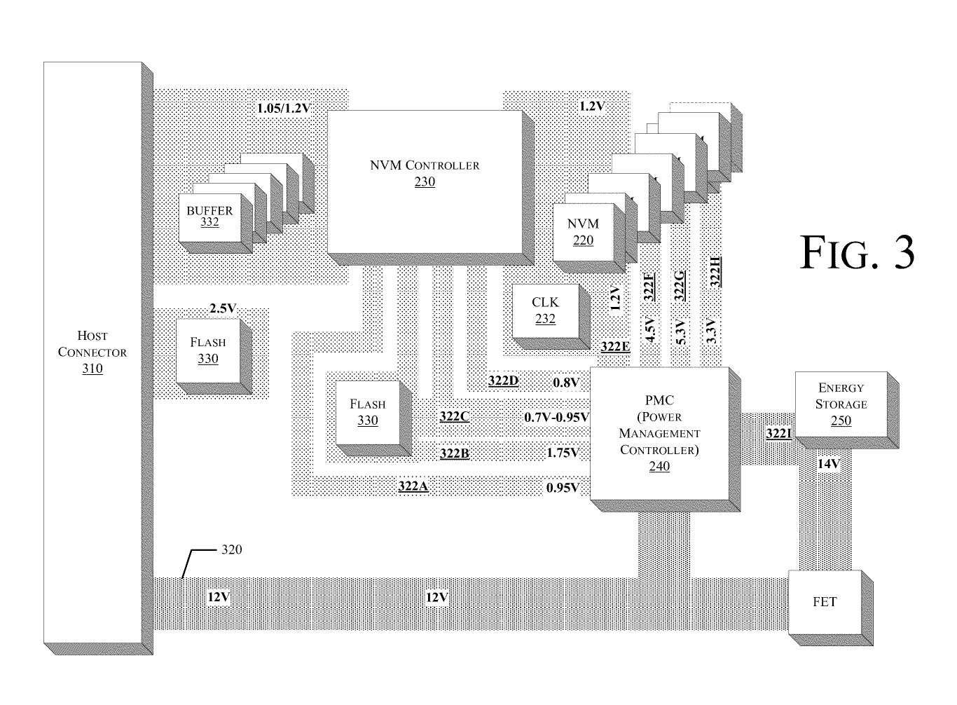

FIG. 3 is a schematic, block diagram of an electrical architecture of a nonvolatile memory module 200 such as memory module 200, which may be implemented in accordance with various embodiments discussed herein. Referring to FIG. 3, in some examples the nonvolatile memory module 200 is coupled to a host device via suitable host connector 310. In some examples host connector 310 provides electrical connections including a 12 volt input provided on an input rail 320. Host connector 310 may also provide power to one or more flash memory modules 330 and one or more memory buffers 332.

Electrical power on input rail 320 is provided to power management controller 240. In operation, power management controller 240 receives electrical power from input power rail 320 and distributes electrical power to other components of nonvolatile memory module 200 via output power rails 322A-322J, which may be referred to collectively herein by reference numeral 322. The output power rails 322 provide electrical power to other components of memory module 200 including the memory controller 230, the clock 232, and one or more nonvolatile memory modules 220. Controller 240 also provides power to an energy storage device 250. In some examples energy storage device 250 may be implemented as one or more capacitors, a battery or the like.

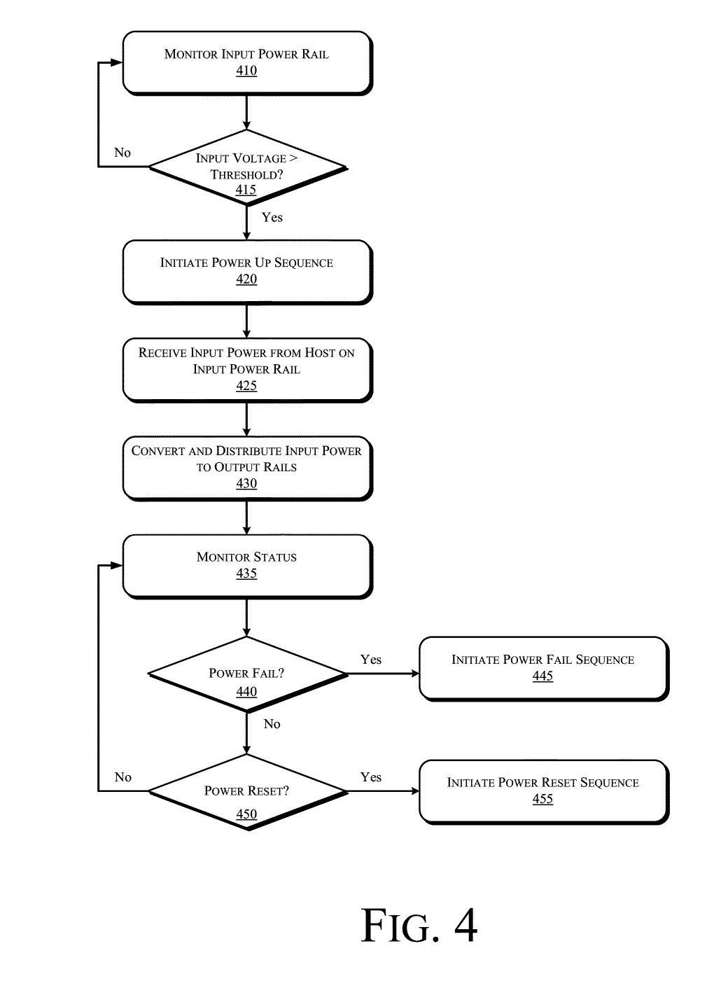

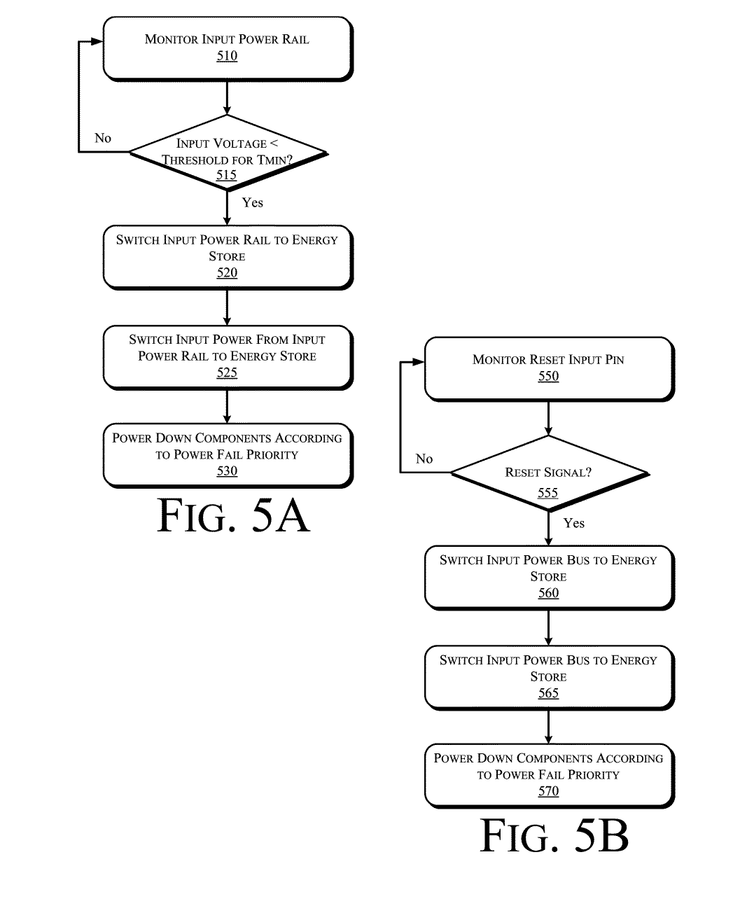

As described above, in some embodiments the controller 240 in the memory module(s) 200 implements power management operations in the memory module 200. Operations implemented by controller 240 and/or driver 162 will be described with reference to FIGS. 4 and 5A-5B.

Referring first to FIG. 4, at operation 410 the power management controller 240 monitors the voltage at the input power rail. At operation 415 the controller 240 determines whether the voltage at the input power bus meets a minimum threshold. If the voltage does not meet the threshold then the controller 240 continues to monitor the input rail. By contrast, if at operation 415 the volage at the input power rail meets or exceeds the threshold then control passes to operation 420 and the controller 240 initiates a power up sequence.

In some examples the power up sequence receives electrical power from the input power rail 320 (operation 425) and then converts and distributes the electrical power to the various components on the memory module 200 via the output rails 322 (operation 430). The converts the electrical power from the input voltage to a voltage appropriate for the component to which the electrical power is distributed. Further, in some examples the power up sequence implements delays in powering up the various output rails 322. The output delays may be variable such that electrical power is provided a a first output power rail after a first delay, and to a second output power rail after a second delay, and so forth. I some examples the controller 240 may provide a constant power output on the respective output rails 322. In other embodiments the controller 240 may generate a varied output voltage on one or more of the output rails 322.

One the power up sequence is complete the controller 240 enters a state in which it monitors the status of the power on the input rail 320. If, at operation 440, a power fail condition is detected then control passes to operation 445 and the controller 240 initiates a power fail sequence. By contrast if no power fail condition detected at operation 440 then control passes to operation 450 and the controller 240 monitors for a power reset condition.

If, at operation 450, a power reset condition is detected then control passes to operation 455 and the controller initiates a power reset sequence. By contrast if no power reset condition detected at operation 450 then control passes back to operation 435. Thus, operations 435-455 define a loop pursuant to which the controller 240 monitors for a power fail condition and/or a power reset condition.

FIG. 5A is a flowchart which describes in greater detail operations involved in the power fail monitoring and power fail sequence. Referring to FIG. 5, at operation 510 the controller monitors the power input rail 320. At operation 515 the controller 240 determines whether the voltage at the input power rail falls below a minimum threshold (e.g., 12V) for a predetermined minimum amount of time (e.g., 10 milliseconds (ms)). If the voltage does not fall below the threshold for the minimum amount of time then the controller 240 continues to monitor the input rail. By contrast, if at operation 515 the voltage at the input power rail meets falls below the threshold for the minimum amount of time then control passes to operation 520 and the controller 240 switches the input power to the controller 240 from the input power rail 320 to the energy store 250. The controller 240 then continues to draw power from the energy stored while it performs an orderly power down components on the memory module in accordance with a power fail priority, which may be stored in a memory on or coupled to controller 240.

FIG. 5B is a flowchart which describes in greater detail operations involved in the power reset monitoring and power fail sequence. Referring to FIG. 5, at operation 550 the controller 240 monitors a reset input pin on the connectors 212. If, at operation 555 the controller 240 fails to detect a reset signal then controller 240 continues to monitor the reset input pin. By contrast, if at operation 555 the controller 240 detects a reset signal then control passes to operation 560 and the controller 240 switches the input power to the controller 240 from the input power rail 320 to the energy store 250. The controller 240 then continues to draw power from the energy stored while it performs an orderly power down components on the memory module in accordance with a power fail priority, which may be stored in a memory on or coupled to controller 240.

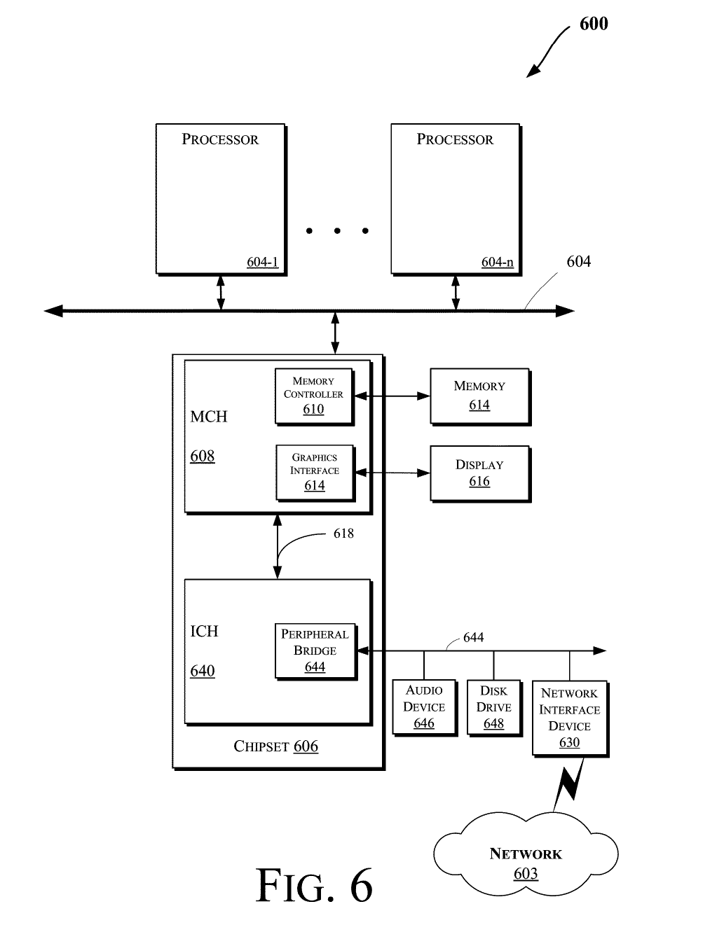

As described above, in some embodiments the electronic device may be embodied as a computer system. FIG. 6 illustrates a block diagram of a computing system 600 in accordance with an embodiment of the invention. The computing system 600 may include one or more central processing unit(s) (CPUs) 602 or processors that communicate via an interconnection network (or bus) 604. The processors 602 may include a general purpose processor, a network processor (that processes data communicated over a computer network 603), or other types of a processor (including a reduced instruction set computer (RISC) processor or a complex instruction set computer (CISC)). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors. In an embodiment, one or more of the processors 602 may be the same or similar to the processors 102 of FIG. 1. For example, one or more of the processors 602 may include the control unit 120 discussed with reference to FIGS. 1-3. Also, the operations discussed with reference to FIGS. 3-5 may be performed by one or more components of the system 600.

A chipset 606 may also communicate with the interconnection network 604. The chipset 606 may include a memory control hub (MCH) 608. The MCH 608 may include a memory controller 610 that communicates with a memory 612 (which may be the same or similar to the memory 130 of FIG. 1). The memory 412 may store data, including sequences of instructions, that may be executed by the CPU 602, or any other device included in the computing system 600. In one embodiment of the invention, the memory 612 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 604, such as multiple CPUs and/or multiple system memories.

The MCH 608 may also include a graphics interface 614 that communicates with a display device 616. In one embodiment of the invention, the graphics interface 614 may communicate with the display device 616 via an accelerated graphics port (AGP). In an embodiment of the invention, the display 616 (such as a flat panel display) may communicate with the graphics interface 614 through, for example, a signal converter that translates a digital representation of an image stored in a storage device such as video memory or system memory into display signals that are interpreted and displayed by the display 616. The display signals produced by the display device may pass through various control devices before being interpreted by and subsequently displayed on the display 616.

A hub interface 618 may allow the MCH 608 and an input/output control hub (ICH) 620 to communicate. The ICH 620 may provide an interface to I/O device(s) that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the CPU 602 and peripheral devices. Other types of topologies may be utilized. Also, multiple buses may communicate with the ICH 620, e.g., through multiple bridges or controllers. Moreover, other peripherals in communication with the ICH 620 may include, in various embodiments of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603). Other devices may communicate via the bus 622. Also, various components (such as the network interface device 630) may communicate with the MCH 608 in some embodiments of the invention. In addition, the processor 602 and one or more other components discussed herein may be combined to form a single chip (e.g., to provide a System on Chip (SOC)). Furthermore, the graphics accelerator 616 may be included within the MCH 608 in other embodiments of the invention.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

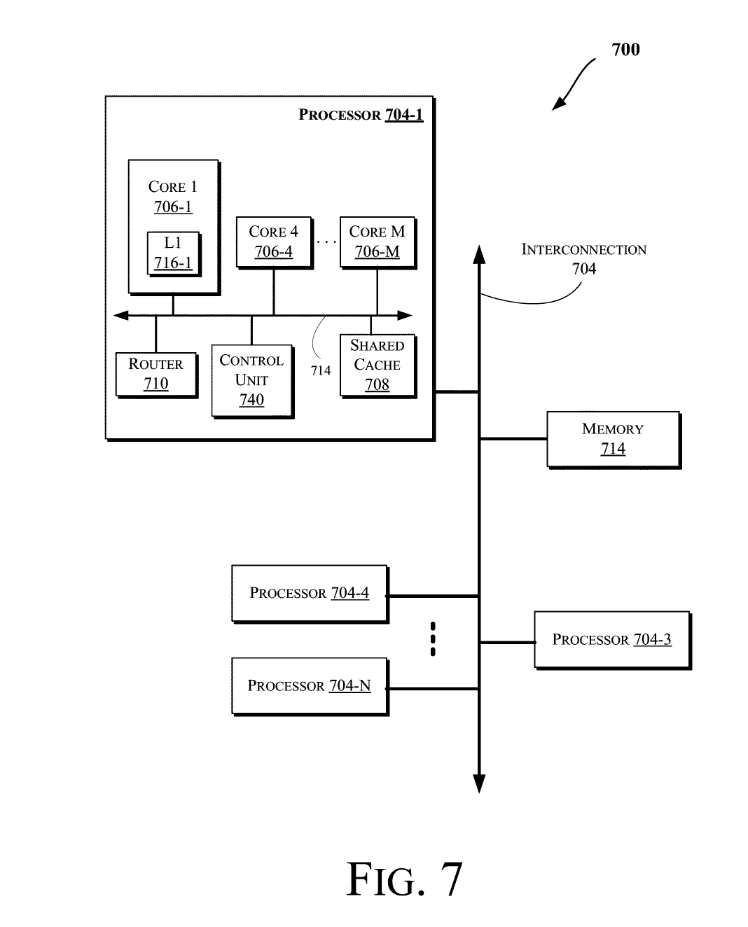

FIG. 7 illustrates a block diagram of a computing system 700, according to an embodiment of the invention. The system 700 may include one or more processors 702-1 through 702-N (generally referred to herein as “processors 702” or “processor 702”). The processors 702 may communicate via an interconnection network or bus 704. Each processor may include various components some of which are only discussed with reference to processor 702-1 for clarity. Accordingly, each of the remaining processors 702-2 through 702-N may include the same or similar components discussed with reference to the processor 702-1.

In an embodiment, the processor 702-1 may include one or more processor cores 706-1 through 706-M (referred to herein as “cores 706” or more generally as “core 706”), a shared cache 708, a router 710, and/or a processor control logic or unit 720. The processor cores 706 may be implemented on a single integrated circuit (IC) chip. Moreover, the chip may include one or more shared and/or private caches (such as cache 708), buses or interconnections (such as a bus or interconnection network 712), memory controllers, or other components.

In one embodiment, the router 710 may be used to communicate between various components of the processor 702-1 and/or system 700. Moreover, the processor 702-1 may include more than one router 710. Furthermore, the multitude of routers 710 may be in communication to enable data routing between various components inside or outside of the processor 702-1.

The shared cache 708 may store data (e.g., including instructions) that are utilized by one or more components of the processor 702-1, such as the cores 706. For example, the shared cache 708 may locally cache data stored in a memory 714 for faster access by components of the processor 702. In an embodiment, the cache 708 may include a mid-level cache (such as a level 2 (L2), a level 3 (L3), a level 4 (L4), or other levels of cache), a last level cache (LLC), and/or combinations thereof. Moreover, various components of the processor 702-1 may communicate with the shared cache 708 directly, through a bus (e.g., the bus 712), and/or a memory controller or hub. As shown in FIG. 7, in some embodiments, one or more of the cores 706 may include a level 1 (L1) cache 716-1 (generally referred to herein as “L1 cache 716”). In one embodiment, the control unit 720 may include logic to implement the operations described above with reference to the memory controller 122 in FIG. 2.

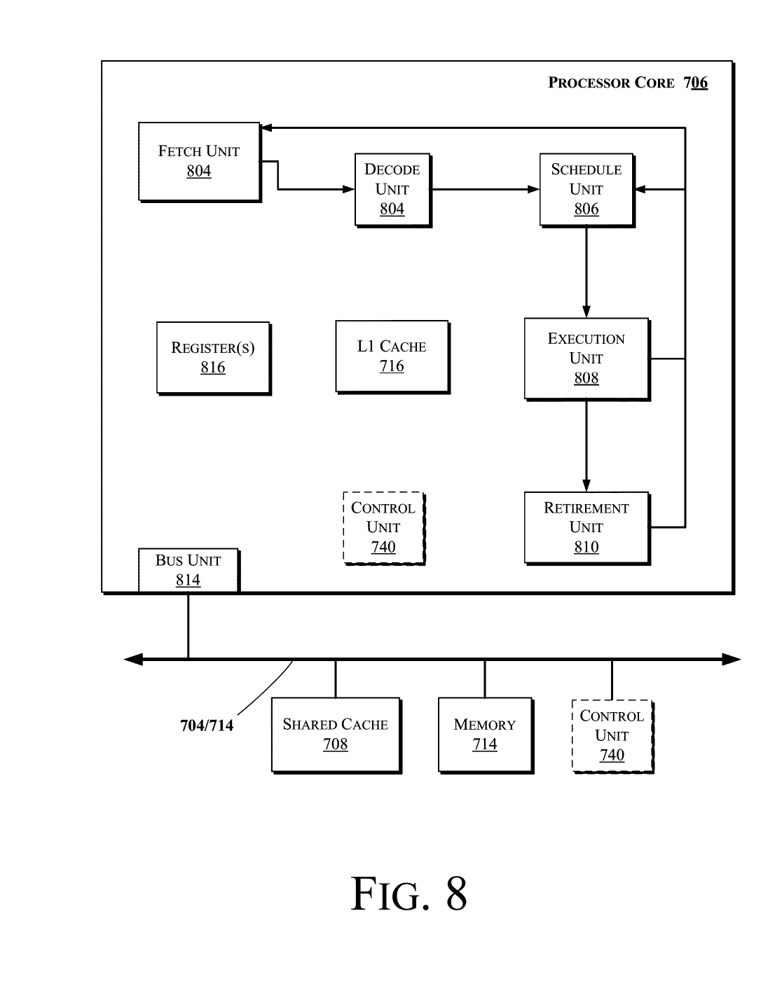

FIG. 8 illustrates a block diagram of portions of a processor core 706 and other components of a computing system, according to an embodiment of the invention. In one embodiment, the arrows shown in FIG. 8 illustrate the flow direction of instructions through the core 706. One or more processor cores (such as the processor core 706) may be implemented on a single integrated circuit chip (or die) such as discussed with reference to FIG. 7. Moreover, the chip may include one or more shared and/or private caches (e.g., cache 708 of FIG. 7), interconnections (e.g., interconnections 704 and/or 112 of FIG. 7), control units, memory controllers, or other components.

As illustrated in FIG. 8, the processor core 706 may include a fetch unit 802 to fetch instructions (including instructions with conditional branches) for execution by the core 706. The instructions may be fetched from any storage devices such as the memory 714. The core 706 may also include a decode unit 804 to decode the fetched instruction. For instance, the decode unit 804 may decode the fetched instruction into a plurality of uops (micro-operations).

Additionally, the core 706 may include a schedule unit 806. The schedule unit 806 may perform various operations associated with storing decoded instructions (e.g., received from the decode unit 804) until the instructions are ready for dispatch, e.g., until all source values of a decoded instruction become available. In one embodiment, the schedule unit 806 may schedule and/or issue (or dispatch) decoded instructions to an execution unit 808 for execution. The execution unit 808 may execute the dispatched instructions after they are decoded (e.g., by the decode unit 804) and dispatched (e.g., by the schedule unit 806). In an embodiment, the execution unit 808 may include more than one execution unit. The execution unit 808 may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit 808.

Further, the execution unit 808 may execute instructions out-of-order. Hence, the processor core 706 may be an out-of-order processor core in one embodiment. The core 706 may also include a retirement unit 810. The retirement unit 810 may retire executed instructions after they are committed. In an embodiment, retirement of the executed instructions may result in processor state being committed from the execution of the instructions, physical registers used by the instructions being de-allocated, etc.

The core 706 may also include a bus unit 714 to enable communication between components of the processor core 706 and other components (such as the components discussed with reference to FIG. 8) via one or more buses (e.g., buses 804 and/or 812). The core 706 may also include one or more registers 816 to store data accessed by various components of the core 706 (such as values related to power consumption state settings).

Furthermore, even though FIG. 7 illustrates the control unit 720 to be coupled to the core 706 via interconnect 812, in various embodiments the control unit 720 may be located elsewhere such as inside the core 706, coupled to the core via bus 704, etc.

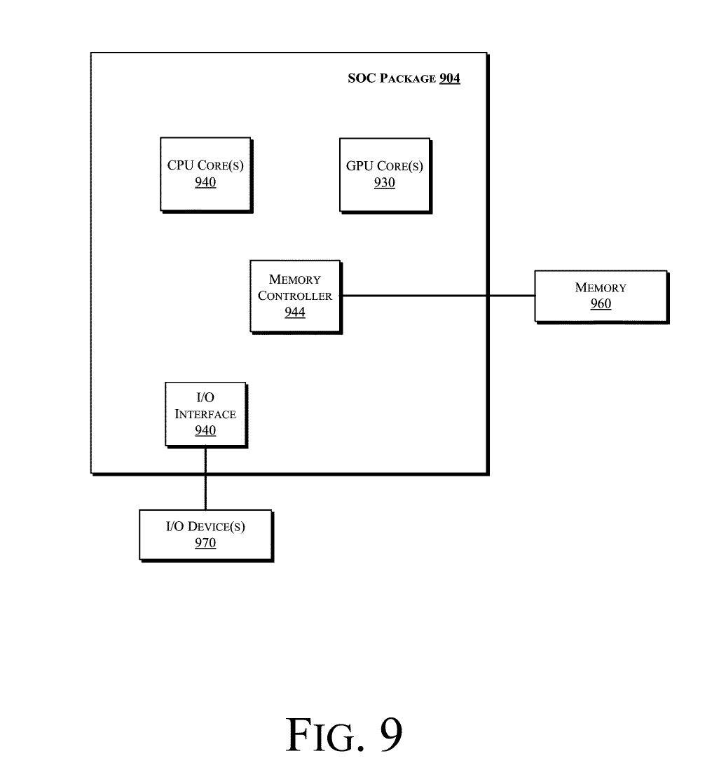

In some embodiments, one or more of the components discussed herein can be embodied as a System On Chip (SOC) device. FIG. 9 illustrates a block diagram of an SOC package in accordance with an embodiment. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 902 may include one or more other components, e.g., as discussed with reference to the other figures herein. In one embodiment, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an embodiment, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch screen, a speaker, or the like.

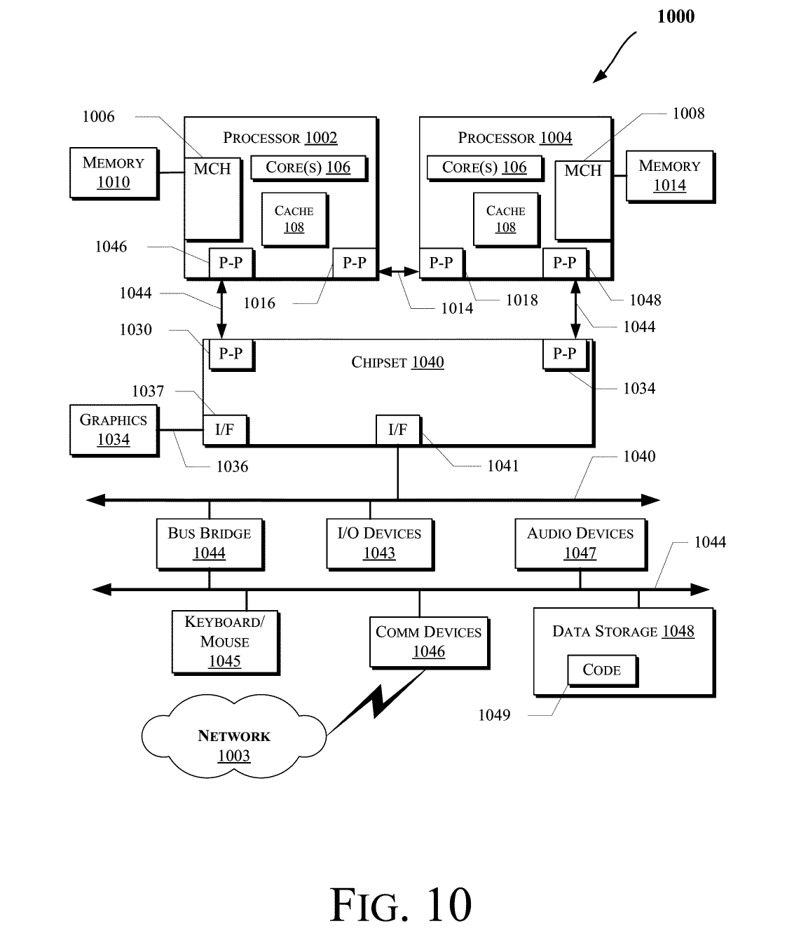

FIG. 10 illustrates a computing system 1000 that is arranged in a point-to-point (PtP) configuration, according to an embodiment of the invention. In particular, FIG. 10 shows a system where processors, memory, and input/output devices are interconnected by a number of point-to-point interfaces. The operations discussed with reference to FIG. 2 may be performed by one or more components of the system 1000.

As illustrated in FIG. 10, the system 1000 may include several processors, of which only two, processors 1002 and 1004 are shown for clarity. The processors 1002 and 1004 may each include a local memory controller hub (MCH) 1006 and 1008 to enable communication with memories 1010 and 1012. MCH 1006 and 1008 may include the memory controller 120 and/or logic 125 of FIG. 1 in some embodiments.

In an embodiment, the processors 1002 and 1004 may be one of the processors 702 discussed with reference to FIG. 7. The processors 1002 and 1004 may exchange data via a point-to-point (PtP) interface 1014 using PtP interface circuits 1016 and 1018, respectively. Also, the processors 1002 and 1004 may each exchange data with a chipset 1020 via individual PtP interfaces 1022 and 1024 using point-to-point interface circuits 1026, 1028, 1030, and 1032. The chipset 1020 may further exchange data with a high-performance graphics circuit 1034 via a high-performance graphics interface 1036, e.g., using a PtP interface circuit 1037.

As shown in FIG. 10, one or more of the cores 106 and/or cache 108 of FIG. 1 may be located within the processors 1004. Other examples, however, may exist in other circuits, logic units, or devices within the system 1000 of FIG. 10. Furthermore, other examples may be distributed throughout several circuits, logic units, or devices illustrated in FIG. 10.

The chipset 1020 may communicate with a bus 1040 using a PtP interface circuit 1041. The bus 1040 may have one or more devices that communicate with it, such as a bus bridge 1042 and I/O devices 1043. Via a bus 1044, the bus bridge 1043 may communicate with other devices such as a keyboard/mouse 1045, communication devices 1046 (such as modems, network interface devices, or other communication devices that may communicate with the computer network 1003), audio I/O device, and/or a data storage device 1048. The data storage device 1048 (which may be a hard disk drive or a NAND flash based solid state drive) may store code 1049 that may be executed by the processors 1004.

The following examples pertain to further examples.

Example 1 is a memory module comprising a nonvolatile memory, an interface to a volatile memory bus, at least one input power rail to receive power from a host platform, and a controller comprising logic, at least partially including hardware logic, to convert the power from the input power rail from an input voltage to at least one output voltage, different from the input voltage

In Example 2, the subject matter of Example 1 can optionally include an arrangement in which a first tension screw to adjust a tension between the first shaft and the first bushing.

In Example 3, the subject matter of any one of Examples 1-2 can optionally include a double data rate synchronous dynamic random access memory (DDRx-SDRAM) bus, a DDR SDRAM bus, or a DDR4 SDRAM bus.

In Example 4, the subject matter of any one of Examples 1-3 can optionally include an arrangement in which the controller comprises logic, at least partially including hardware logic, to vary the output voltage on at least one of the first output rail or the second output rail.

In Example 5, the subject matter of any one of Examples 1-4 can optionally an arrangement in which the controller comprises logic, at least partially including hardware logic, to initiate a power up sequence on the memory module when the power received from the host platform at the input power rail reaches a threshold voltage.

In Example 6, the subject matter of any one of Examples 1-5 can optionally include an arrangement in which the power up sequence implements a first delay before providing power to the first output rail and a second delay before providing power to the second output rail.

In Example 7, the subject matter of any one of Examples 1-6 can optionally include an energy storage device coupled to the memory module.

In Example 8, the subject matter of any one of Examples 1-7 can optionally include an arrangement in which the controller comprises logic to detect a power fail condition, and in response to the power fail condition to implement a power fail sequence.

In Example 9, the subject matter of any one of Examples 1-8 can optionally include an arrangement in which the power fail sequence draws power from at least one energy store coupled to the memory module to provide power to enable an orderly power down of one or more components on the memory module.

In Example 10, the subject matter of any one of Examples 1-9 can optionally include an arrangement in which the controller comprises logic to detect a power reset signal, and in response to the power reset signal to implement a power reset sequence.

In Example 11, the subject matter of any one of Examples 1-10 can optionally include an arrangement in which the power reset sequence draws power from at least one energy store coupled to the memory module to provide power to enable an orderly power down of one or more components on the memory module.

Example 12 is an electronic device, comprising a processor to execute an operating system and at least one application, a memory module comprising a nonvolatile memory an interface to a volatile memory bus, at least one input power rail to receive power from a host platform, and a controller comprising logic, at least partially including hardware logic, to convert the power from the input power rail from an input voltage to at least one output voltage, different from the input voltage

In Example 13, the subject matter of Example 12 can optionally include an arrangement in which a first tension screw to adjust a tension between the first shaft and the first bushing.

In Example 14, the subject matter of any one of Examples 12-13 can optionally include a double data rate synchronous dynamic random access memory (DDRx-SDRAM) bus, a DDR SDRAM bus, or a DDR4 SDRAM bus.

In Example 15, the subject matter of any one of Examples 12-14 can optionally include an arrangement in which the controller comprises logic, at least partially including hardware logic, to vary the output voltage on at least one of the first output rail or the second output rail.

In Example 16, the subject matter of any one of Examples 12-14 can optionally an arrangement in which the controller comprises logic, at least partially including hardware logic, to initiate a power up sequence on the memory module when the power received from the host platform at the input power rail reaches a threshold voltage.

In Example 17, the subject matter of any one of Examples 12-16 can optionally include an arrangement in which the power up sequence implements a first delay before providing power to the first output rail and a second delay before providing power to the second output rail.

In Example 18, the subject matter of any one of Examples 12-17 can optionally include an energy storage device coupled to the memory module.

In Example 19, the subject matter of any one of Examples 12-18 can optionally include an arrangement in which the controller comprises logic to detect a power fail condition, and in response to the power fail condition to implement a power fail sequence.

In Example 20, the subject matter of any one of Examples 12-19 can optionally include an arrangement in which the power fail sequence draws power from at least one energy store coupled to the memory module to provide power to enable an orderly power down of one or more components on the memory module.

In Example 21, the subject matter of any one of Examples 12-20 can optionally include an arrangement in which the controller comprises logic to detect a power reset signal, and in response to the power reset signal to implement a power reset sequence.

In Example 22, the subject matter of any one of Examples 12-21 can optionally include an arrangement in which the power reset sequence draws power from at least one energy store coupled to the memory module to provide power to enable an orderly power down of one or more components on the memory module.

In various embodiments of the invention, the operations discussed herein, e.g., with reference to FIGS. 4-5, may be implemented as hardware (e.g., circuitry), software, firmware, microcode, or combinations thereof, which may be provided as a computer program product, e.g., including a tangible (e.g., non-transitory) machine-readable or computer-readable medium having stored thereon instructions (or software procedures) used to program a computer to perform a process discussed herein. Also, the term “logic” may include, by way of example, software, hardware, or combinations of software and hardware. The machine-readable medium may include a storage device such as those discussed herein.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

1. A memory module comprising:
a nonvolatile memory;
an interface to a volatile memory bus;
at least one input power rail to receive power from a host platform; and
a controller comprising logic, at least partially including hardware logic, to:
convert the power from the input power rail from an input voltage to at least one output voltage, different from the input voltage.

2. The memory module of claim 1, wherein the volatile memory bus comprises at least one of:
a double data rate synchronous dynamic random access memory (DDRx-SDRAM) bus;
a DDR SDRAM bus, or
a DDR4 SDRAM bus.

3. The memory module of claim 1, wherein the controller comprises logic, at least partially including hardware logic, to:
generate a varied output voltage comprising at least a first output voltage on a first output rail to a second output voltage on a second output rail.

4. The memory module of claim 1, wherein the controller comprises logic, at least partially including hardware logic, to:
vary the output voltage on at least one of the first output rail or the second output rail.

5. The memory module of claim 1, wherein the controller comprises logic, at least partially including hardware logic, to:
initiate a power up sequence on the memory module when the power received from the host platform at the input power rail reaches a threshold voltage.

6. The memory module of claim 4, wherein the power up sequence implements a first delay before providing power to the first output rail and a second delay before providing power to the second output rail.

7. The memory module of claim 1, further comprising an energy storage device coupled to the memory module.

8. The memory module of claim 6, wherein the controller comprises logic to detect a power fail condition, and in response to the power fail condition to implement a power fail sequence.

9. The memory module of claim 7, wherein the power fail sequence draws power from at least one energy store coupled to the memory module to provide power to enable an orderly power down of one or more components on the memory module.

10. The memory module of claim 6, wherein the controller comprises logic to detect a power reset signal, and in response to the power reset signal to implement a power reset sequence.

11. The memory module of claim 9, wherein the power reset sequence draws power from at least one energy store coupled to the memory module to provide power to enable an orderly power down of one or more components on the memory module.

12. An electronic device, comprising:
a processor to execute an operating system and at least one application;
a memory module comprising:
a nonvolatile memory;
an interface to a volatile memory bus;
at least one input power rail to receive power from a host platform; and
a controller comprising logic, at least partially including hardware logic, to:
convert the power from the input power rail from an input voltage to at least one output voltage, different from the input voltage.

13. The electronic device of claim 12, wherein the volatile memory bus comprises at least one of:
a double data rate synchronous dynamic random access memory (DDRx-SDRAM) bus;
a DDR SDRAM bus, or
a DDR4 SDRAM bus.

14. The electronic device of claim 11, wherein the controller comprises logic, at least partially including hardware logic, to:
generate a varied output voltage comprising at least a first output voltage on a first output rail to a second output voltage on a second output rail.

15. The electronic device of claim 11, wherein the controller comprises logic, at least partially including hardware logic, to:
vary the output voltage on at least one of the first output rail or the second output rail.

16. The electronic device of claim 11, wherein the controller comprises logic, at least partially including hardware logic, to:
initiate a power up sequence on the memory module when the power received from the host platform at the input power rail reaches a threshold voltage.

17. The electronic device of claim 14, wherein the power up sequence implements a first delay before providing power to the first output rail and a second delay before providing power to the second output rail.

18. The electronic device of claim 11, further comprising an energy storage device coupled to the memory module.

19. The electronic device of claim 16, wherein the controller comprises logic to detect a power fail condition, and in response to the power fail condition to implement a power fail sequence.

20. The electronic device of claim 17, wherein the power fail sequence draws power from at least one energy store coupled to the memory module to provide power to enable an orderly power down of one or more components on the memory module.

21. The electronic device of claim 16, wherein the controller comprises logic to detect a power reset signal, and in response to the power reset signal to implement a power reset sequence.

22. The electronic device of claim 19, wherein the power reset sequence draws power from at least one energy store coupled to the memory module to provide power to enable an orderly power down of one or more components on the memory module.
